(19) United States
(12) Patent Application Publication
(10) Pub. No.: US 2011/0177233 A1
(43) Pub. Date: Jul. 21, 2011

(54) APPARATUS FOR PROVIDING MATERIAL ON A DEPOSITION SURFACE

(75) Inventor: Erwann Picard, Caen (FR)

(73) Assignee: NXP, B.V., Eindhoven (NL)

(21) Appl. No.: 12/519,890

(22) PCT Filed: Jan. 18, 2008
(86) PCT No.: PCT/IB2008/050193

§ 371 Date: Jun. 18, 2009

(51) Int. Cl. C23C 16/455; C23C 16/458

(52) U.S. Cl. 427/58; 118/722; 427/248.1

(57) ABSTRACT

The invention relates to an apparatus (100) for providing a layer of a material from a precursor gas on a deposition surface (112) of a substrate (110). The apparatus includes a deposition chamber (102) and a trap surface (116) for trapping reactive constituents of the precursor gas, the trap surface (116) being arranged such that at least part of the precursor gas flows from a precursor gas inlet (104) along the trap surface (116) before reaching the deposition surface (112) of the substrate (110). The apparatus provides material layers with improved homogeneity

### FIELD OF THE INVENTION

The invention relates to an apparatus for providing a layer of a material from a precursor gas on a deposition surface of a substrate. The invention also relates to the use of the apparatus, and to a method of manufacturing an electronic device therewith.

### BACKGROUND OF THE INVENTION

Processes for depositing a solid film from the precursor gas phase are well known in the art. An often used process is chemical vapor deposition (CVD). CVD is frequently used in semiconductor manufacturing for deposition of films of for example polysilicon, silicon oxide or silicon nitride on semiconductor wafers. A number of CVD variants, of which the best known are low pressure chemical vapor deposition (LPCVD) and plasma enhanced chemical vapor deposition (PECVD) is disclosed in for example the book by S. Wolf and R. N. Tauber, entitled: ‘Silicon Processing for the VLSI Era, Volume 1 Process Technology, 2^{nd} edition lattice Press 2000 hereafter referred to by Ref 1.

CVD is defined as the formation of a solid film on a substrate by the reaction of vapor phase chemicals in the form of reactant precursor gases. The reactant precursor gases contain the constituents of the solid film to be formed. The precursor gas, being a given composition of reactant precursor gasses, is introduced into a deposition chamber of a CVD apparatus. The precursor gas moves from the inlet to the outlet of the deposition chamber in what is called: ‘the main precursor gas flow region’. As the substrate is comprised within the deposition chamber and within the main precursor gas flow region, the precursor gas reaches the surface of the substrate such that the solid film may be formed.

Among the different types of CVD apparatuses (see for example Ref 1), one often used type is the large batch deposition reactor in which batches of typically 50 wafers or more are processed per deposition run. Usually these wafers are stacked side by side a few millimeters apart in a quartz wafer holder often called ‘boat’. The boat is placed in the deposition chamber of the apparatus, which has the shape of a tube that can often be heated. An example of an apparatus and boat are disclosed in WO 2004/113228 A2.

### SUMMARY OF THE INVENTION

It is a disadvantage of the above-mentioned apparatus that the thickness of a deposited layer of material on a substrate shows high non-uniformity across the deposition area.

It is an object of the invention to provide an apparatus with which layers of improved quality can be deposited.

The invention is defined by the independent claims. The dependent claims define advantageous embodiments.

The object is achieved if the deposition chamber comprises:

a trap surface for trapping reactive constituents of the precursor gas, the trap surface being arranged such that at least part of the precursor gas flows from a precursor gas inlet along the trap surface before reaching the deposition surface of the substrate.

The invention is based on the following considerations and insights. In a number of CVD processes, precursor gases are used that comprise reactive constituents generated by decomposition of one or more reactants of the precursor gases. Such reactive constituents may form agglomerates or particles either in the precursor gas or at specific positions where the precursor gas reaches the deposition surface of the substrate. It is these reactive constituents and the associated irregularities during deposition that amongst others are responsible for the non-uniformity and/or reduced quality of the deposited layers.

The deposition irregularities cannot be avoided by removing the reactive constituents form the precursor gas at just any arbitrary point in time before deposition. This is due to the fact that the precursor gas decomposition is continuous in time, i.e. the reactive constituents are generated continuously in the gas phase. To prevent substantial reforming of the reactive constituents in the time period defined by their removal from the precursor gas and the actual deposition on the deposition surface, removal of reactive constituents is preferably performed close to the deposition surface inside the deposition chamber. The required distance that the precursor gas may travel after removal of reactive constituents before the gas reaches the deposition surface is determined by the deposition parameters within the deposition chamber as well as the nature of the components of the precursor gas.

The invention makes use of these insights and the fact that the reactive constituents are “sticky” due to their high reactivity, i.e. they have a high tendency for (permanent) adhesion to other materials such as those of a trap surface. This ensures that the sticking probability of such reactive constituents to a trap surface is high. Therewith, the invention enables relatively efficient filtering of the precursor gas without using complicated filter structures. This in turn enables simplified filter constructs that can be used close to the deposition surface such as inside the deposition chamber where often little space is available. Simple filter constructs are also advantageous in view of the fact that deposition surfaces often are heated to high temperatures posing stringent requirements on the deposition chamber as well as anything that resides inside them during deposition such as the substrate holders and other components.

In an embodiment the substrate holder is configured such that after entering of the precursor gas into the deposition chamber, the precursor gas flows over the deposition surface of the substrate from an edge of the deposition surface and the trap surface is located near the edge of the deposition surface. In various types of CVD apparatuses, the substrates are positioned within the main precursor gas flow region such that the precursor gas reaches the deposition surface at one or more positions of the edge of the deposition surface before flowing over the deposition surface. In view of the regeneration of reactive constituents as described above, it is advantages if the trap surface is positioned near the edge of the deposition surface.

If regeneration of reactive constituents is relatively slow, the trap surface can be located and designed such that it does not extend over the deposition surface of the substrate. The precursor gas therewith flows along the trap surface before reaching the deposition surface. This setup may be advantageous for substrate accessibility during replacement of substrates.

If regeneration of the reactive constituents is relatively fast such that it occurs substantially in precursor gas present above the deposition surface, then the trap surface can be designed and located such that it extends at least partly over or above the deposition surface. This allows capture of reactive particles above the surface.

In an embodiment at least a part of the trap surface includes an angle with the deposition surface of the substrate. In an apparatus according to the previous embodiment, the efficiency of the trap surface is increased when the trap surface comprises a portion that inclines with the deposition surface. The inclined part creates turbulence of the precursor gas such that better contact of the precursor gas and the trap surface is achieved. Numerous shapes of trap surfaces can be designed by those skilled in the art that will result in improved trap function. Shapes include corrugated surfaces, roughened surfaces bent surfaces and the like. The shape of the surface may be advantageously used to direct the precursor gas flow.

In an embodiment the deposition chamber comprises a cage enclosing the substrate, the cage having at least one opening for entering of the precursor gas. The precursor gas flow in the vicinity of the substrate, which is inside the cage will to some extent be governed by the opening for entering of the precursor gas. Hence the cage regulates the precursor gas flow. In one aspect the cage will slow down and stabilize the precursor gas flow in the vicinity of the substrate. This will enhance the trapping efficiency of the trap surface, since more time is available for trapping. In another aspect, the opening defines the position from where the precursor gas can reach the deposition surface. Therewith, the position of the opening in the cage with respect to the trap surface can be used to optimize the trapping efficiency.

In one variation, the trap surface is present inside the cage and extends from the opening to the deposition surface.

In an embodiment the substrate holder is configured for holding a plurality of substrates each of which has a deposition surface, the substrates being held by the substrate holder in such a way that the deposition surfaces are substantially parallel but not in the same plane, and the apparatus comprising a plurality of trap surfaces each of the trap surfaces being associated with one of the plurality of substrates and arranged such that at least part of the precursor gas reaches the deposition surface of one of the plurality of substrates by flowing along the trap surface associated with that substrate. In a substrate holder according to this embodiment, each substrate is associated with a trap surface, i.e. each corresponding deposition surface on a substrate has its own trap surface. Hence, multiple substrates can be processed in one run benefiting from the advantages of a trap surface in the same way. Thus, all trap surfaces may have the same geometry and/or distance from their associated deposition surface, therewith providing uniform deposition results across the batch of substrates processed in one run.

In a variation of that present embodiment, multiple substrates may have different trapping surfaces to achieve different deposition results in one run. The embodiment is advantageous when substrates have the shape of flat sheets or panes such as with semiconductor wafers, since a large number of such substrates can be held in substrate holder according to the embodiment for batch processing. The substrate holder in this embodiment furthermore is usually used in a so called horizontal tube reactor apparatus. This apparatus is much cheaper than a vertical furnace apparatus, the latter having intrinsically better deposition results, but lower throughput. The invention therefore will advantageously result in substantially lower production cost in case of the horizontal tube apparatus.

In an embodiment the substrate holder is configured for holding the plurality of substrates in such a way that two neighboring substrates have their deposition surfaces facing each other, and that each of at least a number of the plurality of trap surfaces is arranged to be located near the edge of at least one of the two facing deposition surfaces of the two neighboring substrates. In this embodiment, the deposition surfaces of two neighboring substrates define a volume in between the facing deposition surfaces. The volume is accessible from the open side. It is advantageous to locate the trap surfaces in the vicinity of the open sides, therewith gaining substantial control over the precursor gas conditions within the volumes between two deposition surfaces. Therewith, the conditions for deposition on two neighboring substrates are substantially identical, which increases deposition uniformity across substrates of one batch run.

In an embodiment according to the previous two embodiment the cage is configured such that it comprises a top portion and a bottom portion that may be combined to enclose the substrate holder and the trap surface is attached to the cage. In this embodiment, attachment of the trap surfaces onto a top portion that functions as a lid that covers the enclosed substrates, easy substrate exchange is provided through removal of the top portion. In the mean time, accurate positioning of the trap surfaces with respect to the substrates is guaranteed. In addition, the trap surfaces, which may be delicate structures are supported by the cage. The apparatus of the invention may be used with advantage for the deposition of layers. These layers will have improved properties, among which a better uniformity of the layer. This better uniformity particularly relates to a better uniformity of the thickness of the deposited layer. The use of the improved apparatus appears particularly suitable for the deposition of layers in three-dimensional structures. Examples of such structures are cavities, trench structures, for instance for trench capacitors and for through-hole vias. As will be understood, an adequate deposition of a layer will be more difficult if the angle between a surface and a side wall of the structure is larger (with a maximum of 90 degrees, particularly between 80 and 100 degrees, more specifically between 85 and 95 degrees) and also if the aspect ratio of the structure is higher (particularly for an aspect ratio between height and diameter of more than 5, and more preferably more than 10). If a layer is deposited insufficiently in such a three-dimensional structure, this may lead to yield loss. For instance when a dielectric is deposited insufficiently, the breakdown voltage goes down and the dielectric constant goes up. If a void turns up, a short circuit is made. When a conductive layer is deposited insufficiently, the internal resistance of a device may go up tremendously, up to the limit wherein the device does not operate anymore due to lack of contact. However, the insufficient deposition also may lead to voids which have a negative impact on the reliability of a device comprising the trench structure. One of the problems with non-uniform deposition across a wafer, is the lack of options to counteract the non-uniformity—in wafer processing it is virtually impossible to decrease deposition rate for a specific area on the wafer only. The invention to provide adequate means to decrease reaction rate of the gases. This may be exploited most beneficially to allow the gases to enter such three-dimensional structures. Therewith, the deposition inside a three-dimensional structure can be made more uniform and more similar to that on a planar wafer surface.

### BRIEF DESCRIPTION OF THE DRAWINGS

These and other aspects of the invention will be elucidated by the following description and drawings in which:

FIGS. 1A and 1B each schematically show an apparatus according to an embodiment of the invention,

FIGS. 2A and 2B, schematically show an apparatus according to an embodiment of the invention comprising a substrate holder for holding multiple substrates, and

FIGS. 3A, 3B and 3C schematically show an embodiment of a substrate holder comprising a cage and trapping surface according to an embodiment of the invention.

### DESCRIPTION OF EMBODIMENTS

In the following description a number of embodiments of an apparatus according to the invention are described and the effect of the invention elucidated. The embodiments described concern CVD deposition of material layers on semiconductor substrates, which may include semiconductor wafers. However, other substrates may be used and the apparatuses can be adjusted according to need by those skilled in the art without departing from the scope of the invention. The invention is useful in for example low pressure CVD, (LPCVD), plasma enhanced CVD (PECVD) or the like.

Polysilicon deposition is used as the critical process in order to elucidate the workings of the invention by way of example. The invention is not limited to this process and those skilled in the art will be able to think of other deposition processes for which the invention provides the advantages described. Such processes include for example deposition of silicon oxide and silicon nitride.

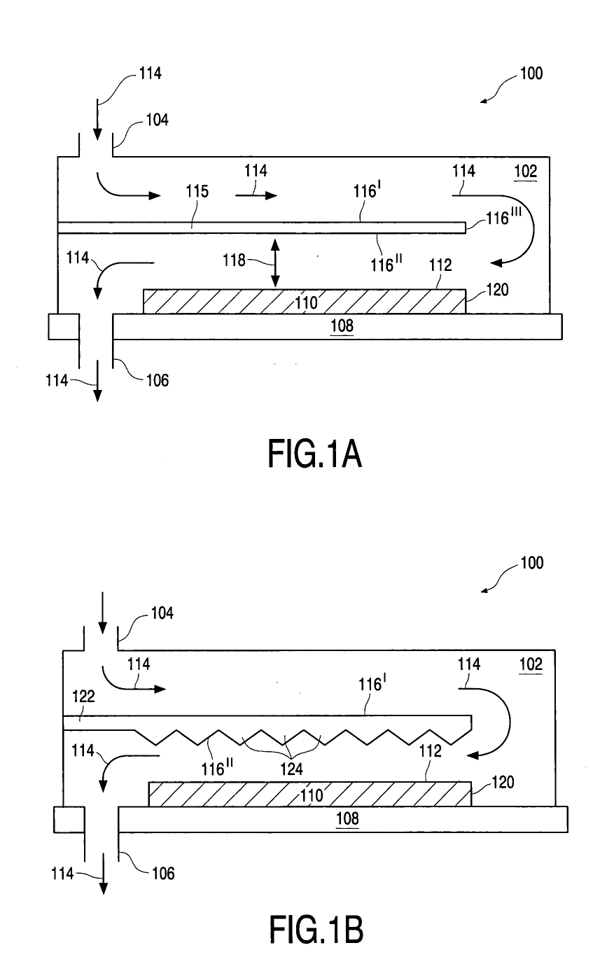

FIGS. 1A and 1B schematically represent two embodiments of an exemplary apparatus according to the invention. The corresponding constituents in both Figures have identical numbers which will be explained together with reference to FIG. 1A. Different parts have different numbering and will be explained separately.

In a first embodiment an apparatus 100 comprises a deposition chamber 102, having a precursor gas inlet 104, a precursor gas outlet 106, and a substrate holder 108. A substrate 110 having a deposition surface 112 is held by and supported by the substrate holder 108. The deposition surface has an edge that coincides with the edge 120 of the substrate. The precursor gas flow is indicated by the arrows 114. A screen 115 provides a trap surface 116 arranged to be located in the precursor gas flow 114. The trap surface 116 comprises portions 116′, 116″ and 116′″.

After entering of the precursor gas into the deposition chamber 102 through the precursor gas inlet 104, the precursor gas flows along the portion 116′ before reaching the deposition surface 112 at its edge 120. Subsequently, the precursor gas flows along portion 116″ while it also flows along the deposition surface 120. The precursor gas flows over the deposition surface 112 before exiting the deposition chamber 102 through the precursor gas outlet 114. The presence of portion 116″ is advantageous for trapping reactive constituents within the precursor gas that are generated within the precursor gas flow region in between the deposition surface 112 and the screen 115, i.e. trapping occurs close to area of the entire deposition surface during deposition.

In the present embodiment the portions 116′ and 116″ of the trap surfaces are substantially parallel with the deposition surface 112, while the small portion 116′″ is not. The portions 116′ and 116″ are not inclined with the deposition surface 112. Portion 116″ faces the deposition surface 112 and defines a distance 118 with the deposition surface 112.

In precursor gases of different deposition processes, different reactive constituents having different sticking tendency are generated at generally different rate. The higher this rate, the less time is available between the instant of trapping of reactive constituents and the generation of new reactive constituents. Hence, in order to create a precursor gas for deposition that is deprived of reactive constituents, trapping must take place at a distance of the deposition surface that is not too large. This distance is of course related to the flow speed of the precursor gas. Furthermore, those skilled in the art will recognize that the level of removal of reactive constituents will also be related to contact time of the precursor gas with the trapping surface and the part of the volume of precursor gas that comes into contact with the trapping surface.

The apparatus according to the invention can be advantageously designed such as to optimally taking into account the considerations described in the previous paragraph. Thus, with reference to FIG. 1A, the orientation of the inclination and/or shape and/or relative position of the trap surface with respect to the deposition surface 112 can be chosen according to need. Thus for example: decreasing the distance 118 by moving screen 115 towards the deposition chamber will increase the trapping efficiency.

In an embodiment, as shown in FIG. 1B, surface 116″ of screen 122 has protrusions 124 for creating turbulence within the gas flow which enhances the trapping function of the trap surface. Also the effective area of the trap surface region 116″ in FIG. 1B is increased with respect to the corresponding surface 116″ in FIG. 1A by using the protrusions 124. Alternatively, scores or irregular patterns may be used to design the trapping surface. Although the features such as the protrusions and scores in theory may have any shape desired, those skilled in the art will know that some will have optimum effects in terms of gas flow and the sticking tendency of the reactive constituents. The trap surface can be bent or curved and even corrugated to increase the contact of precursor gas and trap surface.

In an embodiment one or more of the parameters of the trap surface such as its distance towards, or the angle with which it is inclined with the deposition surface can be adjusted during a deposition process. This allows convenient optimization of trapping and hence uniform layer deposition during deposition.

In the embodiments described here before, the precursor gas can only reach the deposition surface from the edge 120 of the deposition surface 112. This however does not need to be the case. In other embodiments, the precursor gas flow is such that gas reaches the deposition surface 112 at some center portion and flows over the substrate towards some edge portion.

In an embodiment, the trap surface 116 is divided into multiple smaller ones, that can be individually optimized for generating the most effective trapping situation in a specific deposition chamber using a specific substrate and deposition process. For example, the trap surface 116 may comprise one or more holes through which the precursor gas may reach the deposition surface. The one or more holes may comprise tubes.

The individual trapping surfaces may be part of a precursor gas distribution system present within the deposition chamber. Such systems include cages having one or more precursor gas entrance slots or tubes having multiple precursor gas outlets distributed across the deposition surface. The one or more trap surfaces may be attached to these distribution systems or the substrate holders.

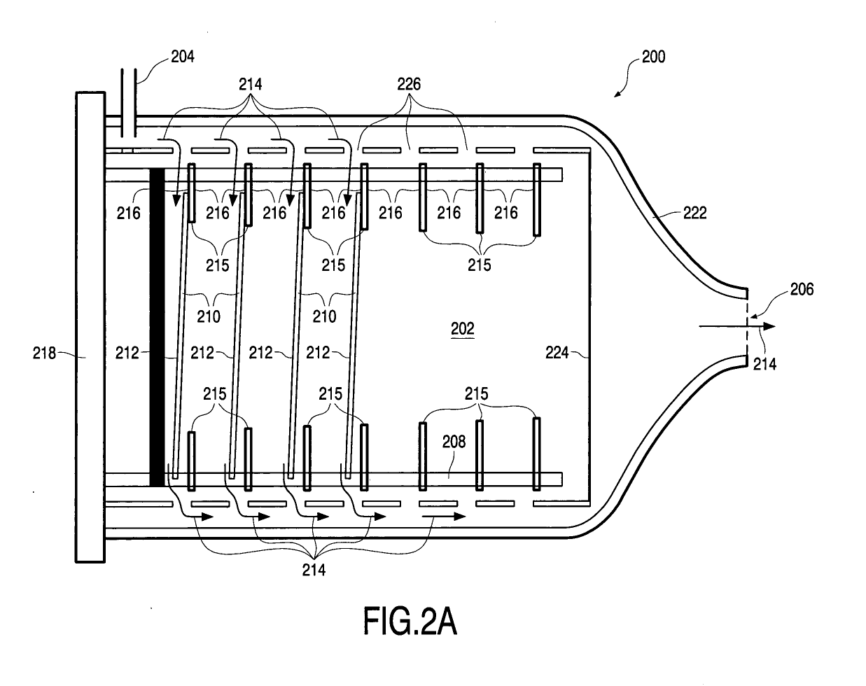

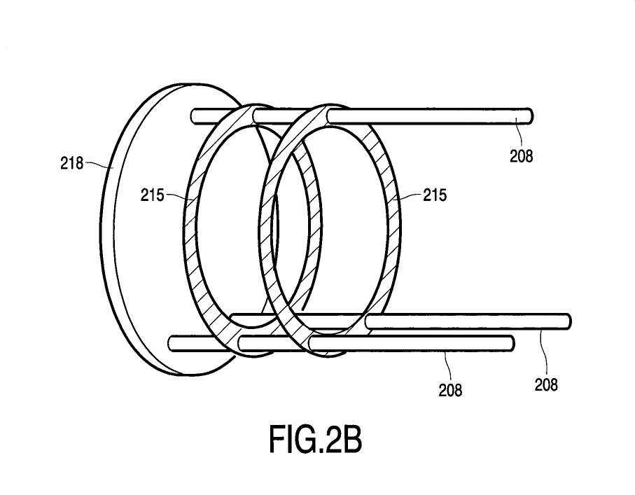

An embodiment of the apparatus according to the invention is shown in FIGS. 2A and 2B. The apparatus 200 comprises a deposition chamber 202 within a tube 222 made of for example quartz. The apparatus 200 is equipped with a gas inlet 204 for entering of the precursor gas into the deposition chamber 202 and a gas exhaust 206 for exiting of gas. The lid 218 seals the tube 222. A substrate holder comprising a number of parallel rods 208 each having notches for holding a plurality of substrates 210 is attached to the lid 218. To the rods 208 are attached ring shaped screens 215 that provide the trap surfaces 216 on either of their sides. The substrates 210 are positioned in the substrate holder (for clarity the substrates are omitted from FIG. 2B) such that the edge of each substrate 210 is in between two trap surfaces 216 of neighboring screens 215.

The apparatus comprises a cage 224 that is configured for enclosing the substrate holder and the substrates. Although in this case the cage encloses the substrate holder and the substrates entirely, this does not need to be the case in alternative apparatuses. The cage 224 comprises slots or openings 226 for letting the precursor gas enter the cage in such a way that the slots force the precursor gas to flow along the trap surfaces 216 before reaching the deposition surfaces 212. Each deposition surface is associated with a trap surface. The cage 224 may be connected to the lid 218, the substrate holder or the apparatus. However, the trap surface design and orientation is preferably tuned to the slots of the cage for optimum trapping function.

As shown in FIG. 2B, the lid 218 and the substrate holder 208 can be disconnected from the apparatus in order to exchange the substrates.

In an alternative embodiment, the cage is omitted or the or the trap surfaces are attached to the cage.

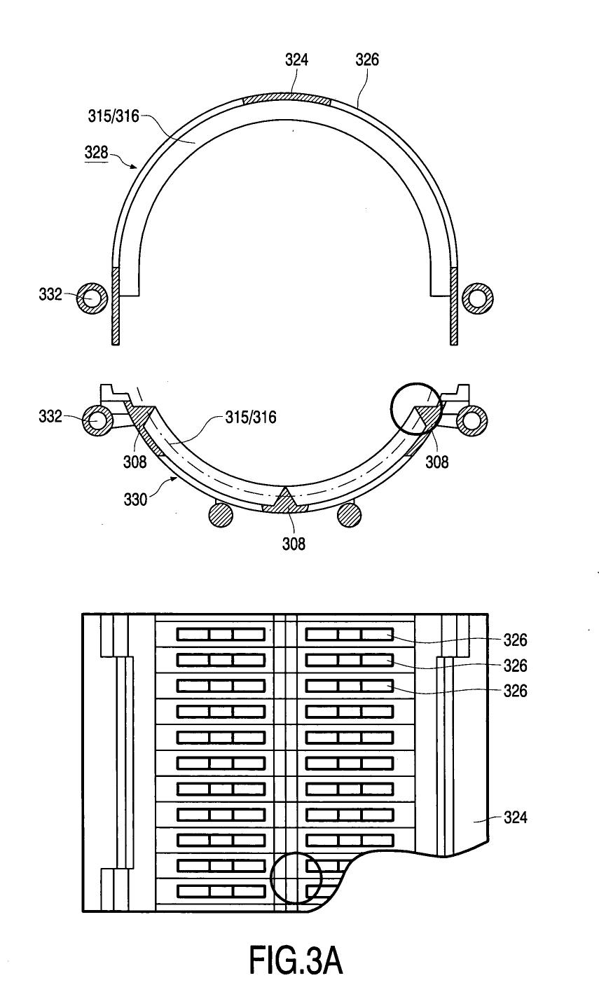

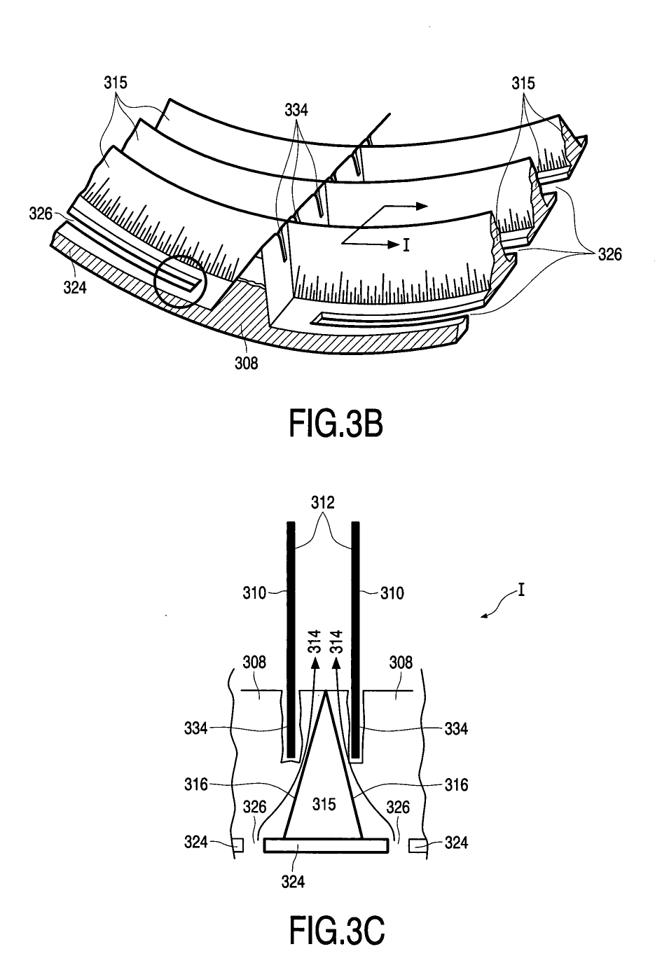

In an embodiment the substrate holder is not attached to the lid 218. In stead the apparatus comprises a separate substrate holder 308 (see FIG. 3A) which is often called a boat, that can be removed from and inserted in the tube 222 via opening of the lid 218. In this case it is convenient when the trap surfaces are attached to the substrate holder and not to the deposition chamber in view of facile substrate replacement.

In the case that a cage as described is present, it is advantageous although not necessary that the trap surfaces 316 are attached or molded to the cage 324. The advantage being ease of handling and/or strength of the system that also the substrate holder 308 is integrated with the cage 324 and the trap surfaces 316. An embodiment of such a design is shown in FIGS. 3A and 3B.

The cage 324 has the shape of a shell and comprises an upper portion 328 and a bottom portion 330 that can be connected to each other via means 332. The bottom portion 330 comprises rods 308 in the length direction of the shell. The rods 308 comprise notches 334 for holding the substrates 310 (not shown in FIGS. 3A and 3B) parallel at a defined distance from each other. Both the upper portion 328 and the bottom portion 330 comprise slots or openings 326 for entering of precursor gas into the cage 324. Both portions also comprise wedge shaped parts 315 which provide trapping surfaces 316 according to the invention in either side of the sharp edges of the wedges. Hence, the trap surfaces 316 extend in between the substrates (see particularly FIG. 3C).

Preferably, substrates 310 are held such that all deposition surfaces face a trap surface of a wedge. Therewith, the deposition surfaces of two neighboring substrates face each other. In this way precursor gas that enters through the slots 326 has to pass along (see arrows 114 in FIG. 3C) the trap surface before reaching the deposition surfaces of the substrates. Therewith the substrate holder can be efficiently loaded with substrates 310. Furthermore, uniformity of deposition conditions is further increased since two deposition surfaces define a space between them wherein the same deposition conditions apply.

In the embodiments the drawings show exaggerated distances. Usually one substrate holder may comprise 50 substrates or more, leaving just a few millimeters of space in between neighboring substrates. Hence, the trap surfaces, if extending between wafers must be thin too. The substrates may be stacked horizontally or vertically, and the trap surfaces oriented conform on of the two types. Stacking of substrates such that the deposition surfaces face downward or such that these surfaces are oriented vertically have the advantage of less particle contamination as those skilled in the art will appreciate.

The slots 326 for entering of the gas are parallel to the wedge shaped components 315, but other geometrical arrangements can be employed without departing from the scope of the invention.

For all embodiments the trap surfaces described may be prepared from the usual materials used to manufacture the apparatus and/or the substrate holder and/or the cages. The materials used will depend on the type of apparatus and processes employed during deposition as those skilled in the art will know. For example, when high temperatures are used during the deposition often quartz is used for creating the substrate holders. It is then from a manufacturing point of view advantageous if the trap surfaces are integrated with the substrate holder to also make them from quartz.

However, the trap surface may be advantageously modified chemically, physically or both in order to increase the trapping efficiency and/or specificity. This enables possibility to realize specific reactive constituents to be trapped. Chemical modification includes all measures that increase trapping efficiency with respect to the non modified trapping surface. For example a carbon surface can be generated. Those skilled in the art will be able to devise the chemical modifications according to their need.

The trap surface may also be physically modified for the above purpose. Thereto it may be provided with small particles or other methods to create for example a rough surface in order to influence precursor gas flow and increase the effective trapping surface area. To this end a carbon or silicon coating may be provided. Other coating materials may be employed also to simultaneously create the specific trapping function described in the previous paragraph.

The deposition chamber may be equipped with a pressure gauge at the gas inlet or vacuum gauge at the gas outlet for adjusting the gas flow speed in combination with the trap surface design in order to adjust the system to the generation rate of reactive constituents.

The substrate holder may be designed such that the substrate rotates around an axis perpendicular to the deposition surface in order to obtain further layer deposition homogeneity.

Trap surfaces of the second and first embodiment having the substrate holders for batch substrate processing may have other shapes and distances or orientations towards the substrates with the associated advantages described. Thus, the wedge shaped components may be constructed such that the trap surfaces extend substantially between the substrates therewith trapping reactive constituents very close to the deposition surfaces. The apparatuses can be constructed such that the trap surfaces can be reoriented and positioned during a deposition process providing convenient adjustment of parameters for process optimization.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element or product does not exclude the presence of a plurality of such elements or products. The mere fact that certain measures are recited in mutually different dependent claims does not indicate that the combination of these measures cannot be used to advantage.

1. An apparatus for providing a layer of a material from a precursor gas on a deposition surface of a substrate, the apparatus having a deposition chamber including:
a trap surface for trapping reactive constituents of the precursor gas, the trap surface being arranged such that at least part of the precursor gas flows from a precursor gas inlet along the trap surface before reaching the deposition surface of the substrate.

2. An apparatus as claimed in claim 1 wherein the deposition chamber further includes a substrate holder configured such that after entering of the precursor gas into the deposition chamber, the precursor gas flows over the deposition surface of the substrate from an edge of the deposition surface towards a central portion of the deposition surface, and the trap surface is located near the edge of the deposition surface.

3. An apparatus as claimed in claim 1 wherein at least a part of the trap surface is inclined to the deposition surface of the substrate.

4. An apparatus as claimed in claim 1 wherein the deposition chamber comprises a cage enclosing the substrate, the cage having at least one opening for entering of the precursor gas.

5. An apparatus as claimed in claim 2 wherein
the substrate holder is configured for holding a plurality of substrates each comprising a deposition surface, the substrates being held by the substrate holder in such a way that the deposition surfaces are substantially parallel but not in the same plane, and
the apparatus comprising a plurality of trap surfaces each of the trap surfaces being associated with one of the plurality of substrates and arranged such that at least part of the precursor gas reaches the deposition surface of one of the plurality of substrates by flowing along the trap surface associated with that substrate.

6. An apparatus as claimed in claim 5 wherein
the substrate holder is configured for holding the plurality of substrates in such a way that two neighboring substrates have their deposition surfaces facing each other, and that
each of at least a number of the plurality of trap surfaces is arranged to be located near the edge of at least one of the two facing deposition surfaces of the two neighboring substrates.

7. An apparatus as claimed in claim 4 characterized in that,
the cage is configured such that it comprises a top portion and a bottom portion that are configured to be combined for enclosing the substrate holder and the trap surface is attached to the cage.

8. Use of the apparatus according to claim 1 for the provision of a material from a precursor gas on a deposition surface.

9. A method of manufacturing an electronic device comprising the provision of a material as claimed in claim 8.

10. A method as claimed in claim 9, wherein the material is deposited in a trench structure in a substrate of the device.
